(19) United States
(12) Patent Application Publication
(10) Pub. No.: US 2012/0326243 A1
(43) Pub. Date: Dec. 27, 2012

(54) TRANSISTOR HAVING ALUMINUM METAL GATE AND METHOD OF MAKING THE SAME

(76) Inventors: Hsin-Fu Huang, Tainan City (TW); Chi-Mao Hsu, Tainan City (TW); Min-Chuan Tsai, New Taipei City (TW); Chin-Fu Lin, Tainan City (TW); Chun-Hsien Lin, Tainan City (TW)

(21) Appl. No.: 13/165,795

(22) Filed: Jun. 22, 2011

(51) Int. Cl. H01L 21/336; H01L 29/78

(52) U.S. Cl. 257/410; 438/287; 257/E21.444; 257/E29.255

(57) ABSTRACT

A transistor having an aluminum metal gate includes a substrate, a high-k gate dielectric layer, an aluminum metal gate and a source/drain region. The high-k gate dielectric layer is disposed on the substrate. The aluminum metal gate includes a work function tuning layer and an aluminum metal layer disposed orderly on the high-k gate dielectric layer, where the aluminum metal layer comprises a first aluminum metal layer and a second aluminum metal layer. Furthermore, the source/drain region is disposed in the substrate at each of two sides of the aluminum metal gate.

### BACKGROUND OF THE INVENTION

1. Field of the Invention

The present invention relates to a transistor having a metal gate and a method for making the same, and more particularly, to a transistor having a metal gate made of an aluminum metal layer with narrower grain size distribution and a method for making the same.

2. Description of the Prior Art

With a trend towards scaling down the size of metal-oxide-semiconductors (MOS), the thickness of a gate dielectric layer must be reduced; however, if the gate dielectric layer is insufficient for sustaining a breakdown voltage, the phenomenon of serious leakage current will occur. Additionally, boron penetration from the polysilicon gate results in a deterioration of the device performance. Therefore, the semiconductor industry tends to use metal gates and high-K (high dielectric constant) materials to replace the conventional polysilicon gate and silicon oxide gate dielectric layer.

For facilitating the high-K materials used as gate dielectric layers, metal gates are usually comprised of a work function tuning layer and a metal layer with low resistance, where the material used in the metal layer includes aluminum. Accordingly, how to fabricate an aluminum metal gate having better quality to improve the reliability of transistor performance is still an important issue in the field.

### SUMMARY OF THE INVENTION

An objective of the present invention is to provide a transistor having a metal gate and a method for making the same to improve the reliability of transistor performance.

According to one exemplary embodiment of the present invention, the method of fabricating a metal gate includes the following steps. First, a substrate is provided, and a dummy gate structure is formed thereon. Then, an opening is formed in the dummy gate structure. Furthermore, the step of forming an aluminum metal layer to fill the opening includes performing a pre-deposition step for forming the first aluminum metal layer in the opening and performing a deposition step for forming the second aluminum metal layer on the first aluminum metal layer.

According to another exemplary embodiment of the present invention, the transistor having an aluminum metal gate is provided. The transistor includes a substrate, a high-k gate dielectric layer disposed on the substrate, an aluminum metal gate, and a source/drain region disposed in the substrate at each of two sides of the aluminum metal gate. Furthermore, the aluminum metal gate includes a work function tuning layer and an aluminum metal layer disposed orderly on the high-k gate dielectric layer, where the aluminum metal layer comprises a first aluminum metal layer and a second aluminum metal layer.

The present invention utilizes a two-step process for forming the aluminum metal layer of the metal gate, and the two-step process includes the pre-deposition step for the formation of the first aluminum metal layer and the deposition step for the formation of the second aluminum metal layer. An average process temperature of the pre-deposition step is substantially smaller than an average process temperature of the deposition step; additionally, the fluid such as argon (Ar) air is not introduced at the backside of the substrate for heat transfer in the pre-deposition step. The two-step aluminum deposition process decreases the number of pin-hole defects and narrows the grain size distribution of the aluminum metal layer to facilitate the reliability of transistor performance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 6 illustrate a method for forming a transistor having a metal gate according to a preferred embodiment of the present invention.

FIG. 7 illustrates a transistor having an aluminum metal gate according to another preferred exemplary embodiment of the present invention.

### DETAILED DESCRIPTION

To provide a better understanding of the present invention, preferred exemplary embodiments will be described in detail. The preferred exemplary embodiments of the present invention are illustrated in the accompanying drawings with numbered elements.

To eliminate the pin-hole defects caused by the wide grain size distribution of an aluminum metal layer in the physical vapor deposition (PVD) process, the present invention provides a two-step process for forming the aluminum metal layer having a narrower grain size distribution. Please refer to Table. 1. Table. 1 illustrates the gate-fill process steps of the first exemplary embodiment and the second exemplary embodiment. As shown in Table. 1, the process steps of the first exemplary embodiment include: pre-heating, aluminum metal deposition and post-dep reflow. Furthermore, a comparison between the process steps of the first exemplary embodiment and the process steps of the second exemplary embodiment shows that the “pre-heating” step is excluded and the “aluminum metal deposition” step is split into two steps in the second exemplary embodiment. In other words, the “aluminum metal deposition” step in the first exemplary embodiment is performed under a fixed process temperature, while the two-step process of aluminum metal deposition in the second exemplary embodiment is performed under a floating process temperature. The two-step process includes a pre-deposition step for forming a first aluminum metal layer and a deposition step for forming a second aluminum metal layer, where an average process temperature of the pre-deposition step is substantially smaller than an average process temperature of the deposition step; additionally, a heater controlling the process temperature during the process is disposed at the backside of the substrate which the aluminum metal layer is supposed to deposit on. For obtaining the uniform heat transferred to the substrate and the stable process temperature, the fluid such as argon (Ar) air used for heat transfer is introduced at the backside of the substrate. In the pre-deposition step, the fluid used for heat transfer is not introduced at the backside of the substrate, for example, the argon (Ar) air is not introduced at the backside of the wafer. Moreover, the process time of the post-dep reflow step could be changed for adjusting the thermal budget, for example, the process time of the post-dep reflow step in the second exemplary embodiment could be increased for compensating the thermal budget loss due to the excluded pre-heating step.

TABLE 1

| Gate-fill | | | | Post-dep |
|---|---|---|---|---|
| process steps | Pre-heating | Aluminum metal deposition | | reflow |
| The first | V | Deposition step | | V |
| exemplary | | V | | |
| embodiment | | | | |
| The second | X | Pre-deposition | Deposition | V |
| exemplary | | step | step | |
| embodiment | | V | V | |

It should be appreciated that the aluminum metal layer of the first exemplary embodiment has a rough surface with pin-hole defects because of the wide grain size distribution, and the deviation of grain size distribution also exists between different transistors. The smoother surface of the aluminum metal layer of the second exemplary embodiment, however, has fewer pin-hole defects and a larger refractive index; that is, the two-step process of aluminum metal deposition in the second exemplary embodiment can be used to form the aluminum metal layer having a narrower grain size distribution, which facilitates the reliability of the transistor performance.

The present invention may be applied in various semiconductor processes such as the interconnect process and the metal gate process etc. The second exemplary embodiment and the high-k first process integrated into the gate-last process are combined as a preferred exemplary embodiment. Please refer to FIG. 1 through FIG. 6. FIG. 1 through FIG. 6 illustrate a method for forming a transistor having a metal gate according to a preferred exemplary embodiment of the present invention. As shown in FIG. 1, a substrate 11, such as a silicon substrate or a silicon-on-insulator (SOI) substrate, is provided, in which a plurality of shallow trench isolations (STI) 12 are formed in the substrate 11. Then, an interfacial layer 13, a high-k gate dielectric layer 14, an etching stop layer 15, a dummy gate layer 16 and a cap layer 17 are formed on the overall substrate 11. The method of forming these layers includes any kind of deposition process: for instance, chemical vapor deposition (CVD) or physical vapor deposition (PVD) etc., but it is not limiter thereto. Furthermore, the interfacial layer 13 is optionally formed on the substrate 11 for strengthening the adhesion between the high-k gate dielectric layer 14 and the substrate 11. The material of the interfacial layer 13 may be silicon oxide, nitridation silicon oxide or other low-k material, but is not limiter thereto. Additionally, the high-k gate dielectric layer 14 may be a metal oxide layer such as a rare-earth metal oxide layer. The material of the high-k gate dielectric layer 14 may be hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or any combination thereof. The etching stop layer 15 made of titanium nitride (TiN) or tantalum nitride (TaN), but not limiter thereto, may be optionally formed between the high-k gate dielectric layer 14 and the dummy gate layer 16 as a barrier layer for protecting the high-k gate dielectric layer 14 underneath. The dummy gate layer 16 could be composed of undoped polysilicon or polysilicon having N+ dopants therein, and the cap layer 17 disposed on the dummy gate layer 16 could be composed of silicon dioxide (SiO₂), silicon nitride, or silicon oxynitride (SiON), but is not limited thereto.

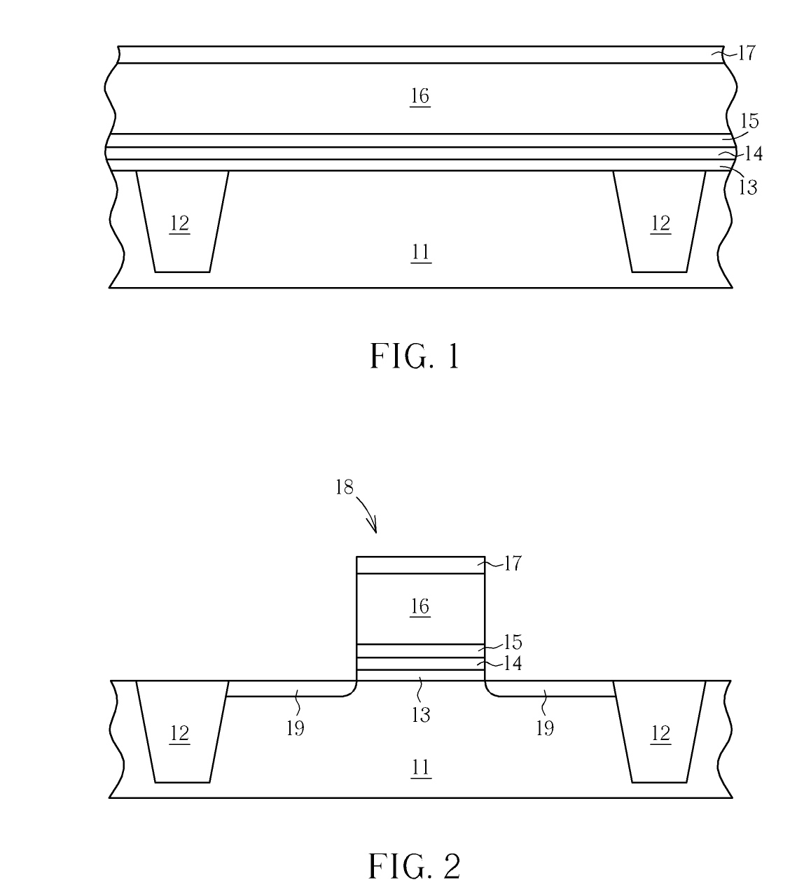

Furthermore, as shown in FIG. 2, a patterned photoresist (not shown) is formed on the cap layer 17, and a pattern transfer is conducted by using the patterned photoresist as a mask through single or multiple etching processes to remove a portion of the cap layer 17, the dummy gate layer 16, the etching stop layer 15, and the high-k gate dielectric layer 14. After stripping the patterned photoresist, a dummy gate structure 18 composed of patterned high-k gate dielectric layer 14, patterned etching stop layer 15, patterned dummy gate layer 16, and patterned cap layer 17 is formed on the substrate 11. Moreover, a light doped source/drain (LDD) region 19 is disposed in the substrate 11 at each of two sides of the dummy gate structure 18.

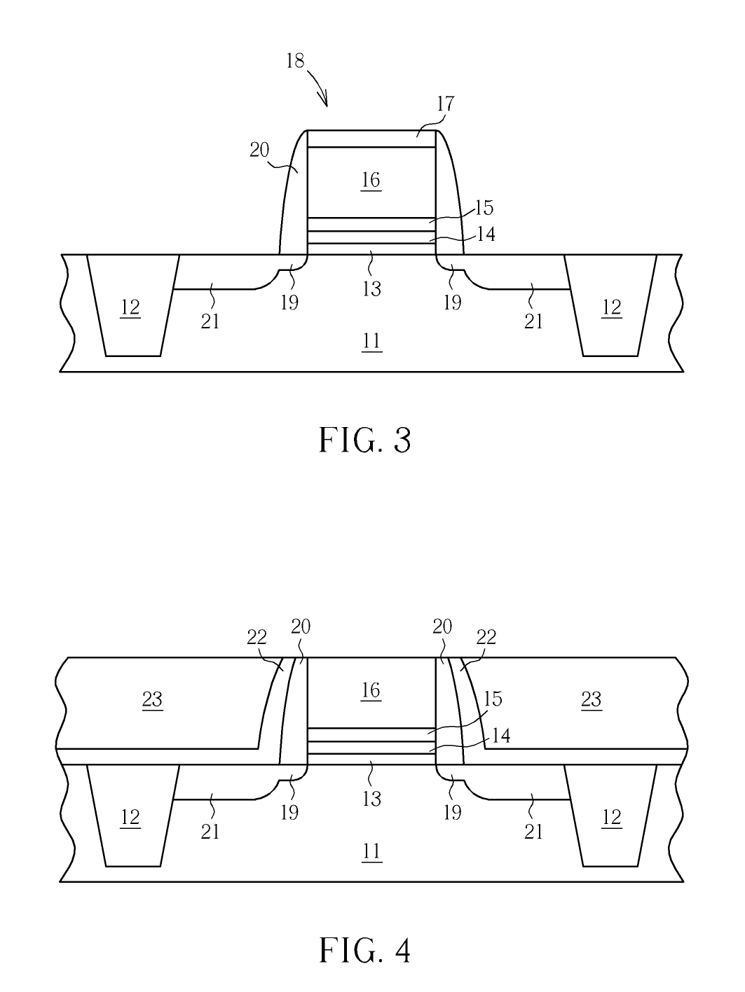

Subsequently, as shown in FIG. 3, a spacer 20 is formed on the sidewall of the dummy gate structure 18, where the spacer 20 may be a monolayered structure or multilayered structure or may include a liner, or be a composition thereof. The material of the spacer 20 could be high temperature oxide (HTO), silicon nitride, silicon oxide, or HCD-SiN formed by hexachlorodisilane (Si₂Cl₆). As the spacer processes are commonly known to those skilled in the art, the details are omitted herein for brevity. A source/drain region 21 is formed in the substrate 11 at each of two sides of the dummy gate structure 18 through an ion implantation process by using the spacer 20 and the cap layer 17 as a mask and implanting suitable n-type or p-type dopants. Furthermore, an annealing process could be carried out to activate the source/drain region 21.

The transistor of the present invention further includes other semiconductor substrates: for example, a silicide layer (not shown) is formed on the source/drain region 21; an epitaxial layer (not shown) including silicon and other materials is formed in the source/drain region 21 by a silicon substrate etching back process accompanying a selective epitaxial growth (SEG) process; or other protective layers. After forming the source/drain region 21 or the silicide layer (not shown), the spacer 20 can be partially or completely removed to produce a desired stress of a contact etch stop layer (CESL) toward the transistor, and the material for the CESL may include (for example) silicon nitride. Moreover, despite the light doped source/drain region 19, the spacer 20, and the source/drain region 21 are formed sequentially in the illustrated exemplary embodiment, the order of fabricating the spacers and doping regions could also be adjusted according to the demands of the product, and these modifications are all within the scope of the present invention.

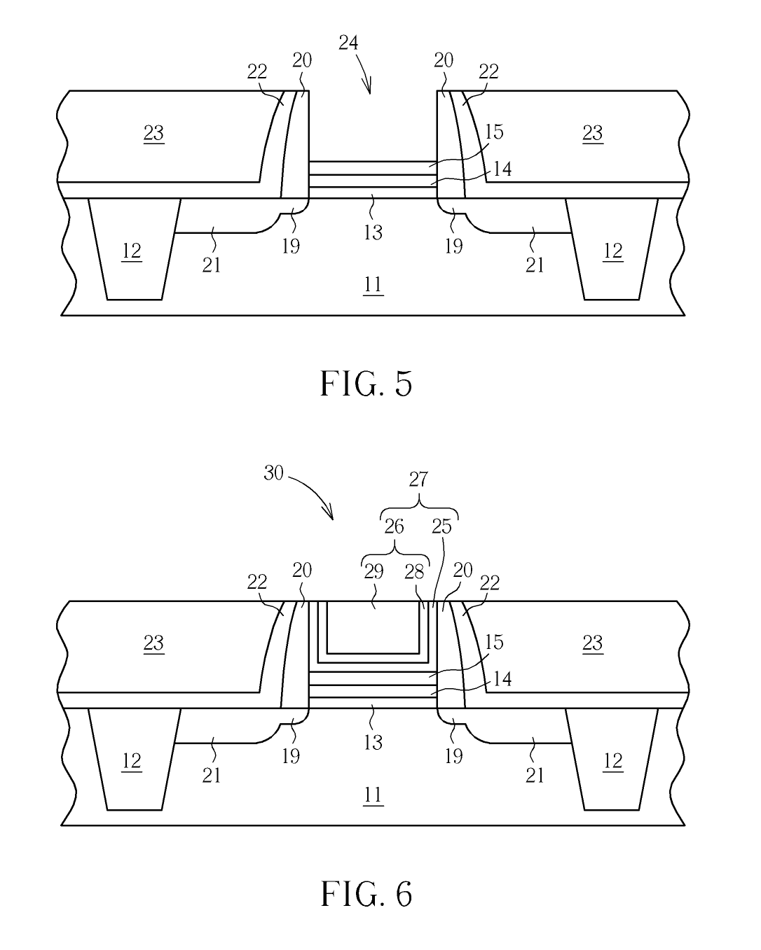

As shown in FIG. 4, a CESL 22 and a inter-layer dielectric (ILD) layer 23 are deposited sequentially to cover the dummy gate structure 18, and a planarization process, such as a chemical mechanical polish (CMP) process or a etching back process, is performed to remove a portion of the ILD layer 23, a portion of the CESL layer 22, a portion of the spacer 20 and all of the cap layer 17 to expose the dummy gate layer 16. Afterwards, as shown in FIG. 5, an opening 24 is formed in the dummy gate structure 18 by performing an etching process to remove the dummy gate layer 16. Meanwhile, the etching stop layer 15 serves as a protective layer of the high-k gate dielectric layer 14. The etching process includes a selective dry etching or wet etching process. In an exemplary embodiment, the dummy gate layer 16 is dry-etched using chlorine gas (Cl₂) as an etchant, and thereafter a tetramethyl ammonium hydroxide (TMAH) solution is used as an etchant to remove the residual dummy gate layer 16, but the invention is not limited thereto.

Please refer to FIG. 5 and FIG. 6 together. A work function tuning layer 25 and an aluminum metal layer 26 are formed to fill the opening 24 for completing a metal gate 27. The work function tuning layer 25 is disposed on the high-k gate dielectric layer 14 and the side walls of the opening 24 for tuning the work function of the metal gate 27 appropriate for an n-type metal oxide semiconductor (NMOS) transistor or p-type metal oxide semiconductor (PMOS) transistor. For use in an NMOS transistor, the work function tuning layer 25 having a work function ranging between 3.9 eV and 4.5 eV may include titanium aluminide (TiAl), zirconium aluminide (ZrAl), tungsten aluminide (WAl), tantalum aluminide (TaAl), or hafnium aluminide (HfAl), but is not limited thereto. For use in a PMOS transistor, the work function tuning layer 25 having a work function ranging between 4.8 eV and 5.2 eV may include titanium nitride (TiN), tantalum nitride (TaN), tantalum carbide (TaC), but is not limited thereto.

It should be appreciated that the present invention utilizes a two-step aluminum metal deposition process to form the aluminum metal layer 26 filling the opening 24. As illustrated previously, the two-step process includes the pre-deposition step and the deposition step. In the pre-deposition step, due to the thermal absorption effect of the substrate 11 just transferred into the tool, the process temperature of the chamber becomes slightly lower, and in order to speed up the thermal equilibrium and thereby save the thermal budget, the fluid such as Ar air originally used to assist thermal transfer is not introduced at the backside of the substrate 11 herein. After a thickness of the first aluminum metal layer 28 formed in the pre-deposition step reaches the pre-determined value, the deposition step starts. In the deposition step, because thermal equilibrium has been achieved, the process temperature of the chamber is stabilized. Accordingly, the second aluminum metal layer 29 formed in the deposition step is under a fixed process temperature, and the fluid such as Ar air used to assist thermal transfer is introduced at the backside of the substrate 11 for stabling the temperature of the substrate 11 herein. The average process temperature of the pre-deposition step is substantially smaller than the average process temperature of the deposition step, and fluid used for heat transfer is not introduced at the backside of the substrate 11 in the pre-deposition step. This two-step aluminum metal deposition process of the present invention can provide the aluminum metal layer 26 having a narrower grain size distribution and larger refractive index. Additionally, after the formation of the work function tuning layer 25 and the aluminum metal layer 26, a planarization process, such as a chemical mechanical polish (CMP) process, may be performed to remove a portion of the work function tuning layer 25 and the aluminum metal layer 26 until the top of the ILD layer 23 is exposed. Consequently, a transistor 30 having the metal gate 27 is fabricated.

In this preferred exemplary embodiment of the present invention, the thickness of the first aluminum metal layer 28 is substantially less than a thickness of the second aluminum metal layer 29, and the thickness of the first aluminum metal layer 28 is substantially less than half the thickness of the aluminum metal layer 26. In the two-step aluminum metal deposition process, the average process temperature and the introduced fluid condition at the backside of the substrate and used for heat transfer are different in the pre-deposition step and the deposition step, while other operation conditions are almost the same. Therefore, as the concentration of the reactant is kept the same for the pre-deposition step and the deposition step, the thickness of the first aluminum metal layer 28 and the second aluminum metal layer 29 could be adjusted by the deposition process time, but is not limited thereto. More specifically, the thickness of the first aluminum metal layer 28 is substantially more than or equal to an eighth of the predetermined thickness of the aluminum metal layer 26, and the thickness of the first aluminum metal layer 28 is substantially smaller than the second aluminum metal layer 29. In other words, when the predetermined thickness of the aluminum metal layer 26 is 4000 angstroms, the thickness of the first aluminum metal layer 28 is substantially between 500 angstroms and 2000 angstroms. Additionally, a refractive index of the aluminum metal layer 26 is proportional to the thickness of the first aluminum metal layer 26; that is, when the thickness of the first aluminum metal layer 26 gets thicker, the aluminum metal layer 26 would have a smoother surface, i.e. the larger refractive index of the aluminum metal layer 26 could be detected. Accordingly, in other exemplary embodiments, the thickness of the first aluminum metal layer 28 is better to be substantially more than or equal to a fifth of the predetermined thickness of the aluminum metal layer 26, and much better to be substantially more than or equal to a third of the predetermined thickness of the aluminum metal layer 26. Additionally, the thickness of the first aluminum metal layer 26 is required to be less than the thickness of the second aluminum metal layer 29.

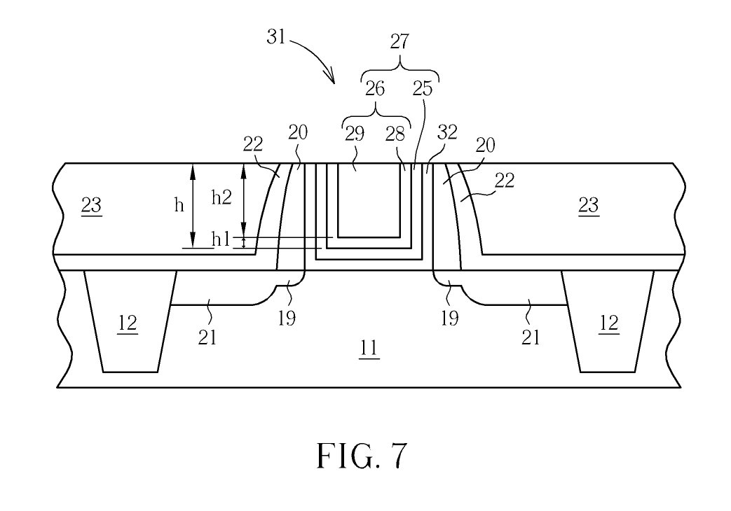

The transistor having an aluminum metal gate of the present invention is not limited to the previous illustrated exemplary embodiment, and the other exemplary embodiment. The combination of the second exemplary embodiment and the high-k last process integrated into the gate-last process will be detailed in the following paragraph. To simplify the explanation and clarify the comparison, in the following exemplary embodiments, the same components are denoted by the same numerals, and the differences are discussed while the similarities are not described again. Please refer to FIG. 7, and refer to FIG. 3 together. FIG. 7 illustrates a transistor having an aluminum metal gate according to another preferred exemplary embodiment of the present invention. As shown in FIG. 7, in this exemplary embodiment, the linear high-k gate dielectric layer 14, the etching stop layer 15, the dummy gate layer 16 and the cap layer 17 of the dummy gate structure 18 are totally removed to form an opening (not shown) exposing a part of the substrate 11. Subsequently, a renewed meal gate structure 31 is formed in the opening. The meal gate structure 31 includes a high-k gate dielectric layer 32 having a U-shaped cross-section and the aluminum metal gate 27. As the processes for forming high-k gate dielectric layer 32 having a U-shaped cross-section are commonly known to those skilled in the art, the details are omitted herein for brevity. Furthermore, the aluminum metal gate 27 includes the work function tuning layer 25 and the aluminum metal layer 26. It should be appreciated that the aluminum metal layer 26 includes the first aluminum metal layer 28 and the second aluminum metal layer 29 formed through the two-step process. A thickness h1 of the first aluminum metal layer 28 is substantially smaller than a thickness h2 of the second aluminum metal layer 29, and the thickness h1 of the first aluminum metal layer 28 is substantially more than or equal to an eighth of a thickness h of the aluminum metal layer 26. In other exemplary embodiments, the thickness h1 of the first aluminum metal layer 28 is better to be substantially more than or equal to a fifth of the thickness h of the aluminum metal layer 26, and much better to be substantially more than or equal to a third of the thickness h of the aluminum metal layer 26. The source/drain region 21 is disposed in the substrate 11 at each of two sides of the aluminum metal gate 27. An interfacial layer is optionally disposed between the substrate 11 and the high-k gate dielectric layer 32 having a U-shaped cross-section for strengthening the adhesion. The material of the interfacial layer may include silicon dioxide or nitridation silicon dioxide, but is not limited thereto.

In conclusion, the present invention utilizes a two-step process for forming the aluminum metal layer of the metal gate, and the two-step process includes a pre-deposition step for the formation of the first aluminum metal layer and a deposition step for the formation of the second aluminum metal layer. An average process temperature of the pre-deposition step is substantially smaller than an average process temperature of the deposition step; additionally, the fluid such as the argon (Ar) air used for heat transfer is not introduced at the backside of the substrate in the pre-deposition step. The two-step aluminum deposition process decreases the number of pin-hole defects and narrows the grain size distribution of the aluminum metal layer to facilitate the reliability of transistor performance.

Those skilled in the art will readily observe that numerous modifications and alterations of the device and method may be made while retaining the teachings of the invention.

What is claimed is:

1. A method for forming a metal gate, comprising:
providing a substrate;
forming a dummy gate structure on the substrate;
forming an opening in the dummy gate structure; and
forming an aluminum metal layer to fill the opening, comprising:
performing a pre-deposition step for forming a first aluminum metal layer in the opening; and
performing a deposition step for forming a second aluminum metal layer on the first aluminum metal layer.

2. The method for forming a metal gate according to claim 1, wherein an average process temperature of the pre-deposition step is substantially smaller than an average process temperature of the deposition step.

3. The method for forming a metal gate according to claim 1, wherein the fluid used for heat transfer is not introduced at the backside of the substrate in the pre-deposition step.

4. The method for forming a metal gate according to claim 1, wherein a thickness of the first aluminum metal layer is substantially smaller than a thickness of the second aluminum metal layer, and the thickness of the first aluminum metal layer is substantially smaller than half a thickness of the aluminum metal layer.

5. The method for forming a metal gate according to claim 4, wherein the thickness of the first aluminum metal layer is substantially more than or equal to an eighth of the thickness of the aluminum metal layer.

6. The method for forming a metal gate according to claim 4, wherein the thickness of the first aluminum metal layer is substantially more than or equal to a fifth of the thickness of the aluminum metal layer.

7. The method for forming a metal gate according to claim 4, wherein the thickness of the first aluminum metal layer is substantially more than or equal to a third of the thickness of the aluminum metal layer.

8. The method for forming a metal gate according to claim 1, wherein a refractive index of the aluminum metal layer is proportional to a thickness of the first aluminum metal layer.

9. The method for forming a metal gate according to claim 1, wherein the dummy gate structure comprises a high-k gate dielectric layer and a dummy gate layer, and the high-k gate dielectric layer is disposed between the substrate and the dummy gate layer.

10. The method for forming a metal gate according to claim 9, wherein a material of the dummy gate layer comprises undoped polysilicon or polysilicon having N+ dopants.

11. The method for forming a metal gate according to claim 9, wherein a material of the high-k gate dielectric layer comprises hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or any combination thereof.

12. The method for forming a metal gate according to claim 9, wherein the dummy gate structure further comprises an interfacial layer disposed between the substrate and the high-k gate dielectric layer.

13. The method for forming a metal gate according to claim 12, wherein a material of the interfacial layer comprises silicon oxide, nitridation silicon oxide or other low-k material.

14. The method for forming a metal gate according to claim 9, wherein the dummy gate structure further comprises an etching stop layer disposed between the high-k gate dielectric layer and a dummy gate layer.

15. The method for forming a metal gate according to claim 14, wherein a material of the etching stop layer comprises titanium nitride (TiN) or tantalum nitride (TaN).

16. The method for forming a metal gate according to claim 14, further comprising forming a source/drain region disposed in the substrate at each of two sides of the dummy gate structure.

17. A transistor having an aluminum metal gate, comprising:
a substrate;
a high-k gate dielectric layer disposed on the substrate;
an aluminum metal gate comprising a work function tuning layer and an aluminum metal layer disposed orderly on the high-k gate dielectric layer, wherein the aluminum metal layer comprises a first aluminum metal layer and a second aluminum metal layer; and
a source/drain region disposed in the substrate at each of two sides of the aluminum metal gate.

18. The transistor having an aluminum metal gate according to claim 17, wherein a thickness of the first aluminum metal layer is substantially smaller than a thickness of the second aluminum metal layer, and the thickness of the first aluminum metal layer is substantially smaller than half a thickness of the aluminum metal layer.

19. The transistor having an aluminum metal gate according to claim 18, wherein the thickness of the first aluminum metal layer is substantially more than or equal to an eighth of the thickness of the aluminum metal layer.

20. The transistor having an aluminum metal gate according to claim 18, wherein the thickness of the first aluminum metal layer is substantially more than or equal to a fifth of the thickness of the aluminum metal layer.

21. The transistor having an aluminum metal gate according to claim 18, wherein the thickness of the first aluminum metal layer is substantially more than or equal to a third of the thickness of the aluminum metal layer.

22. The transistor having an aluminum metal gate according to claim 17, wherein a refractive index of the aluminum metal layer is proportional to a thickness of the first aluminum metal layer.

23. The transistor having an aluminum metal gate according to claim 17, wherein the transistor is an NMOS transistor or a PMOS transistor.

24. The transistor having an aluminum metal gate according to claim 17, wherein the source/drain region comprises an epitaxial layer.

25. The transistor having an aluminum metal gate according to claim 17, wherein the high-k gate dielectric layer comprises a U-shaped cross-section or a linear cross-section.

26. The transistor having an aluminum metal gate according to claim 25, wherein a material of the high-k gate dielectric layer comprises hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or any combination thereof.
